(19) United States
(12) Patent Application Publication
(10) Pub. No.: US 2011/0273290 A1
(43) Pub. Date: Nov. 10, 2011

(54) Door assembly, wall construction, and system for detecting objects near a door and forces applied to a door

(76) Inventor: Jimmy Don Gilchrist, Ben Wheeler, TX (US)

(21) Appl. No.: 12/800,009

(22) Filed: May 6, 2010

(51) Int. Cl. G08B 13/08; E06B 1/04; H01L 31/16; E06B 7/00

(52) U.S. Cl. 340/545.1; 49/70; 52/173.1; 52/210; 250/215

(57) ABSTRACT

An object sensing arrangement is provided in combination with a door that is adapted to be supported for movement from one of an open position and a closed position to the other of the open and closed positions without moving in a first direction in which earth gravitational force acts upon the door. The object sensing arrangement is positioned relative to the door for sensing presence of an object adjacent an end surface of the door that faces in a second direction opposite the first direction. The object sensing arrangement further provides signaling to indicate that object presence is sensed.

### CROSS REFERENCE TO RELATED APPLICATION

This application contains subject matter related to subject matter contained in co-pending U.S. Ser. No. 12/459,289 (docket DCS-1) filed on Jun. 30, 2009 and incorporated herein by reference.

### FIELD

The present work relates generally to door monitoring and, more particularly, to monitoring a door to detect applied forces.

### BACKGROUND

Suicides among patients in mental health treatment facilities and other types of confinement facilities are all too common occurrences. In some instances, the patient or detainee rigs an elongate flexible member, for example a strip of a bed sheet, blanket, curtain, etc., over a door (often the door of the patient or detainee's quarters) in order to hang himself. As an example, the patient/detainee may secure one end of the flexible elongate member to a door handle on one side of the door, and sling the flexible elongate member across the top of the door such that it depends downwardly along the other side of the door. Then, with the door either open or closed, the patient/detainee secures the free end of the flexible elongate member around his neck. The flexible elongate member, rigged generally as described above and secured around the neck of the patient/detainee, supports the body of the patient/detainee above the floor, thereby permitting the patient/detainee to hang himself by the neck until dead.

It is desirable in view of the foregoing to provide for detecting, and signaling an alarm, when a patient/detainee attempts suicide in a manner such as described above.

### BRIEF DESCRIPTION OF THE DRAWINGS

FIG. 1 illustrates a wall construction according to exemplary embodiments of the present work.

FIG. 2 illustrates a portion of FIG. 1 in more detail.

FIG. 3 illustrates a portion of section A-A in FIG. 1.

FIG. 4 illustrates a hinge structure according to exemplary embodiments of the present work.

FIG. 5 is similar to FIG. 2, and illustrates a portion of a door assembly according to further exemplary embodiments of the present work.

FIG. 6 illustrates a solid core door according to exemplary embodiments of the present work.

FIG. 7 illustrates exemplary embodiments that use object sensing arrangements to detect the presence of a ligature rigged over the top of a door.

### DETAILED DESCRIPTION

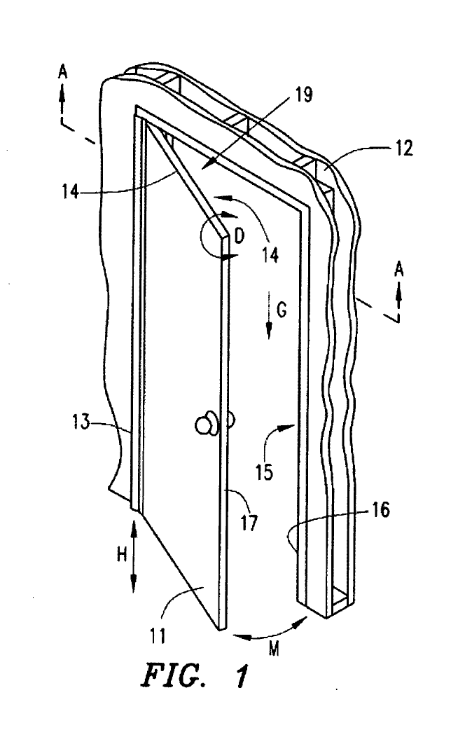

FIG. 1 illustrates a wall construction according to exemplary embodiments of the present work. A doorframe 15 defines a doorway 16 in a wall 12. A door assembly 19 is cooperable with the doorway 16. The door assembly 19 includes a hinge structure 13 affixed to a door 11. The hinge structure 13 is also affixed to the doorframe 15 to mount the door 11 to the wall 12. The wall 12 and the hinge structure 13 support the door 11 for angular, swinging movement about a generally vertically oriented hinge axis H. The movement of the door 11, indicated at M, permits it to assume an open position as illustrated, and a closed position wherein the door occupies and closes the doorway 16. The door assembly 19 also includes pressure sensors 14 secured to upper portions of opposite surfaces of the door 11 and adapted to detect the presence of forces other than the force of gravity G that act on the door in a direction parallel to the direction of the force of gravity.

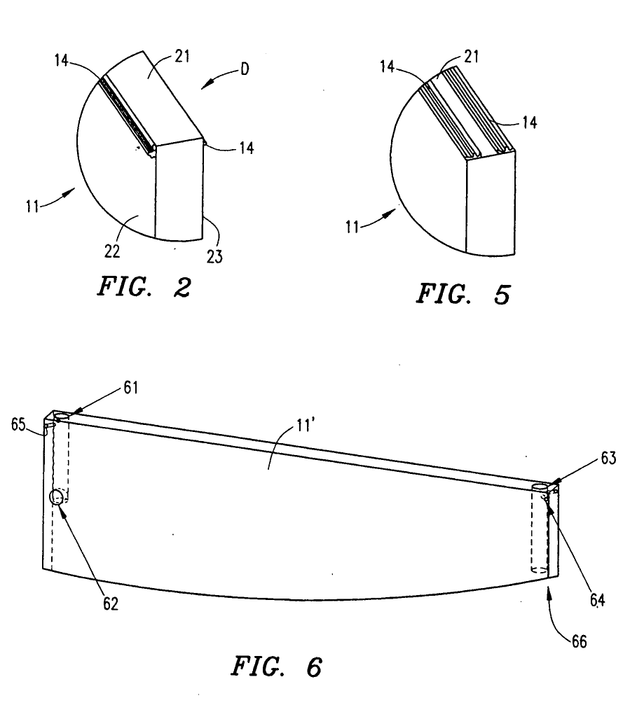

FIG. 2 illustrates a portion D of the door 11 of FIG. 1. As can be seen from FIGS. 1 and 2, the sensors 14 extend along the upper portion of opposite surfaces 22 and 23 of the door 11, across substantially the entire width of the door. In some embodiments, the sensors 14 are secured to the door 11 by a suitable adhesive material. Pressure sensors such as those shown at 14 are well known in the art and readily commercially available. The pressure sensors 14 sense force(s) applied to them, and produce signaling to indicate the presence of the applied force(s).

The sensors 14, as positioned on the surfaces 22 and 23, are capable of detecting the presence of a force applied to the top surface 21 of the door in a direction generally parallel to the force of gravity G. If, for example, a flexible elongate member is rigged across the top surface 21 of the door 11 so as to support the weight of a person's body (as described above), the body weight will cause the elongate member, as it depends downwardly from the top surface 21 under tension, to apply force against at least one of the pressure sensors 14. The sensor(s) will detect the presence of the applied force, and produce signaling to indicate the presence of the force. The sensors 14 are capable of such force detection and signaling while the door 11 is in either the open position or the closed position. Also, and as described in detail hereinafter, the wall construction of FIG. 1 is capable of conducting the signaling from the location of the sensor 14 to a location in the wall 12 for ultimate routing to a control system, whether the door 11 is in the open position or the closed position.

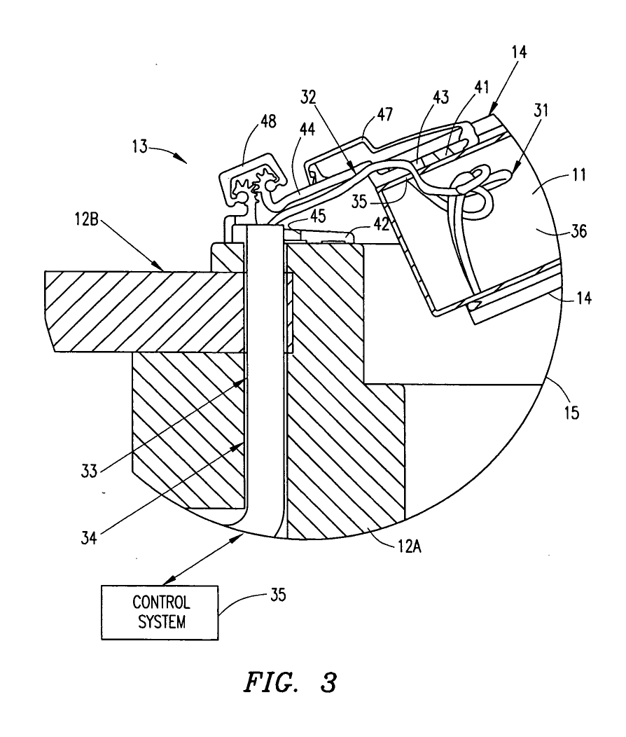

FIG. 3 illustrates a portion of section A-A in FIG. 1, namely, the area around the hinge structure 13. The door 11 of FIG. 3 is a hollow core door. Power and signal lines for the sensors 14 are provided in a cable 32 (a ribbon cable in some embodiments) of electrical wires. The cable 32 passes through an opening 34 that extends through a wall portion 12B and a door jamb portion 12A of the wall 12. A conduit 33 disposed within the opening 34 houses the portion of cable 32 that passes through the wall 12. The cable 32 passes through the conduit 33 to a control system 35. At its other end, the cable 32 emerges from the opening 34 and traverses openings in the hinge structure 13 and the door 11 to reach the interior space 36 of the door 11. There, the signal and power lines are separated, as shown at 31, and are connected to the sensors 14 via suitable openings (not explicitly shown) in the upper portions of the door surfaces 22 and 23 covered by the sensors.

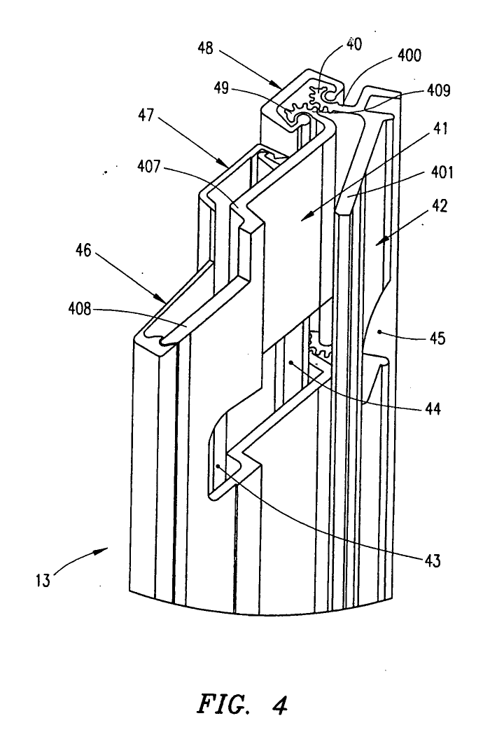

Hinge structures with openings for permitting electrical cabling to traverse the hinge are known in the art. Various embodiments use various ones of those known structures. FIG. 4 illustrates an example of hinge structure 13 according to some embodiments of the present work. The hinge structure 13 of FIG. 4 includes an elongate metal door portion 41 having a flange 408 for attachment to the door 11 by screws or other suitable fasteners (not shown), and an elongate metal frame portion 42 having a flange 401 for attachment to the door frame 15 by screws or other suitable fasteners (not shown). The door and frame portions 41 and 42 are approximately as long as the height of the door 11. The door and frame portions 41 and 42 have respective flanges 400 and 409 with respective gear structures 40 and 49 that are held in mutual engagement by an elongate joint cover 48, forming a hinged joint between the door and frame portions. A cover 47 covers the door portion 41. When the door 11 is in the closed position, the flange 401 of the frame portion 42 is received in a notched section 407 between the flanges 408 and 409 of the door portion 41. Hinge structures of this general construction are known in the art.

The door portion 41 has an opening 43 provided in flange 408, and a slot 44 provided in the notched section 407. The frame portion 42 has an opening 45 provided in flange 401. The openings 43 and 45, together with the slot 44, permit the cable 32 to pass from the wall 12 through the hinge structure 13 and into the interior space 36 of the door 11 (see also FIG. 3).

Referring again to FIG. 3, the opening 45 substantially coincides with the opening 34 in the wall 12, and the opening 43 substantially coincides with an opening 35 in the door 11 to permit the cable 32 to pass into the interior space 36 of the door 11. In some embodiments, the slot 44 is filled with putty to protect the (otherwise exposed) portion of the cable 32 that is disposed within the slot 44.

In various embodiments, the control system 35 includes various combinations of conventional devices (local and/or remote relative to the door) such as audible and visible alarms, visual displays, manually operated switches, electrical power sources, and sensor configuration/control interfaces. In some embodiments, the control system 35 provides operating power for the sensors 14, receives and detects pressure-indicative signaling from the sensors, and responds appropriately (e.g., activates an alarm indication, etc.),

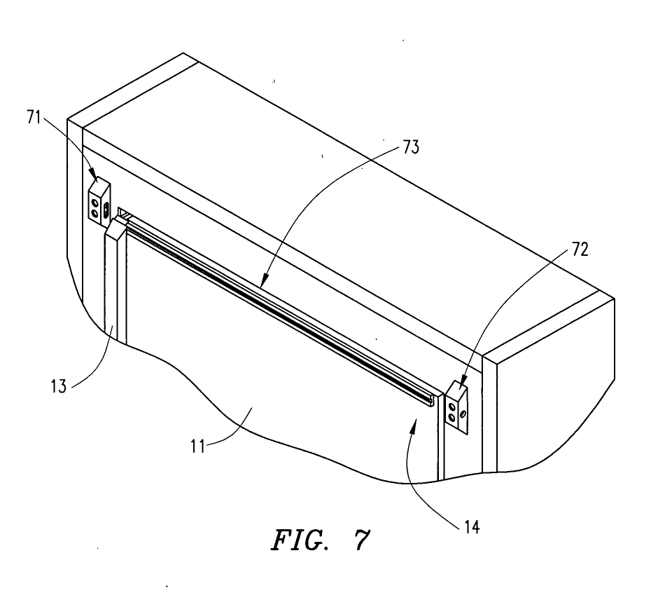

FIG. 5 illustrates alternate embodiments wherein the sensors 14 are provided on and extend substantially the entire length of the top surface 21 of door 11. Such embodiments require appropriate clearance between the sensors 14 and the door frame 15 to prevent false alarms when the door 11 is in the closed position.

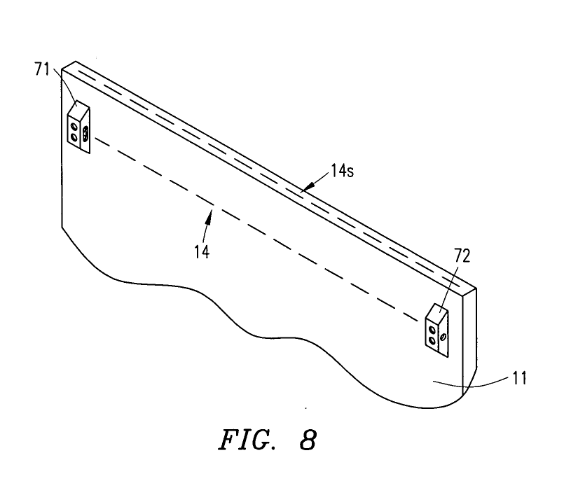

FIG. 6 illustrates embodiments that use a solid door 11′. A vertical bore 61 defines interior space in the door 11′ for the cable 32 and wires 31 (see also FIG. 3). An opening 62 permits the cable 32 to pass from the door 11′ into the opening 43 of the door portion 41 of hinge structure 13 (see also FIG. 4). Some embodiments provide horizontal bores 65 that permit the sensors 14 to be connected in series by wiring that extends between the sensors, passing through the horizontal bores 65 and the vertical bore 64. The series sensor connection may alternatively be provided via a vertical bore 63 and horizontal bores 64 provided in door 11′ near its free end 66.

A series sensor connection may be achieved in hollow core door embodiments by providing, in the portions of surfaces 22 and 23 covered by the sensors 14 (see also FIGS. 1-3), holes suitable for passing the wiring that connects the sensors. Some embodiments locate those holes near the free end 17 of the door 11.

Some embodiments provide an object sensing arrangement for sensing presence of an object adjacent the top surface of the door 11 (such as a ligature rigged over the door). FIG. 7 shows an object sensing arrangement including a source of electromagnetic radiation (one of 71 and 72) and a receiver/detector of electromagnetic radiation (the other of 71 and 72). These components 71 and 72 are mounted on the wall 12 closely adjacent the upper corners of the doorway opening 16 (see also FIG. 1). A beam of electromagnetic radiation emitted by the source is normally received at the receiver. However, if an object is present in the path of the beam, this interruption of the beam is detected by the receiver. The receiver provides signaling (via a suitable conductor within the wall 12) indicating to the control system 35 of FIG. 3 that an object has interrupted the beam.

As is evident from FIG. 7, the components 71 and 72 are positioned relative to the door 11 such that the beam travels from source to receiver in a direction generally parallel to the front surface of the door. In some embodiments, the path of the beam overlies and extends generally parallel to the top surface 73 of the door 11, just below the upper edge of the doorway opening 16. An object that interrupts the beam will be detected.

As shown in FIG. 7, some embodiments combine the object sensing arrangement 71/72 with the FIG. 2 arrangement of pressure sensors 14. Other embodiments combine the object sensing arrangement 71/72 with the FIG. 5 arrangement of pressure sensors 14 (not explicitly shown in FIG. 7). Still other embodiments use the object sensing arrangement 71/72 but omit pressure sensors. In some embodiments, the object sensing arrangement 71/72 is implemented using a dot LED source and a photodiode receiver, such as is commercially available, for example, from SUNX Limited of Kasugai, Aichi, Japan (part number EX23PN).

FIG. 8 illustrates embodiments wherein the components of object sensing arrangement 71/72 are mounted on the front surface of the door 11 adjacent the top of the door. In some embodiments, the path of the beam extends from source to receiver adjacent and generally parallel to the front surface of the door 11, just below the top surface of the door. An object that interrupts the beam will be detected. As shown by broken line in FIG. 8, some embodiments combine the door-mounted object sensing arrangement 71/72 with the FIG. 2 arrangement of pressure sensors 14, and other embodiments combine the door-mounted object sensing arrangement 71/72 with the FIG. 5 arrangement of pressure sensors 14. Still other embodiments use the door-mounted object sensing arrangement 71/72 but omit pressure sensors. In some embodiments, electrically conductive power and signaling connections to the object sensing arrangement 71/72 traverse the hinge structure 13 of FIG. 3 within the cable 32.

In embodiments that combine an object sensing arrangement 71/72 such as shown in FIG. 7 or 8 with the FIG. 2 pressure sensor arrangement, it will of course be recognized that all components are suitably positioned relative to one another such that the pressure sensors 14 do not interrupt the beam between source and receiver.

Although exemplary embodiments of the present work have been described above in detail, this does not limit the scope of the present work, which can be practiced in a variety of embodiments.

What is claimed is:

1. A wall construction, comprising:
a wall having means defining a doorway therein;
a door supported adjacent said wall for movement relative to said doorway from one of an open position and a closed position to the other of said open and closed positions without moving in a first direction in which earth gravitational force acts upon said door;
a sensor positioned on said door for sensing presence of a further force other than earth gravitational force acting on said door in said first direction, and for providing signaling indicative of said presence of said further force; and
an object sensing arrangement positioned relative to said door for sensing presence of an object positioned to apply said further force to said door and providing further signaling indicative of said object presence.

2. The wall construction of claim 1, wherein said object sensing arrangement includes an electromagnetic radiation source for emitting a beam of electromagnetic radiation, and an electromagnetic radiation receiver positioned to receive said electromagnetic radiation beam unless said beam is interrupted by an object.

3. The wall construction of claim 2, wherein said door has a first surface that faces in a second direction perpendicular to said first direction, and wherein said source is positioned to direct said beam substantially parallel to said first surface when said door is in said closed position.

4. The wall construction of claim 3, wherein said source and said receiver are mounted on said wall to be adjacent respective opposite ends of said first surface when said door is in said closed position.

5. The wall construction of claim 4, wherein said door has a second surface that faces in a third direction opposite said first direction, and wherein said source and said receiver are mounted on said wall to be adjacent respective opposite ends of said second surface when said door is in said closed position.

6. The wall construction of claim 5, wherein said sensor is mounted on said first surface.

7. The wall construction of claim 5, wherein said sensor is mounted on said second surface.

8. The wall construction of claim 3, wherein said source and said receiver are mounted on said first surface adjacent respective opposite ends thereof.

9. The wall construction of claim 8, wherein said door has a second surface that faces in a third direction opposite said first direction, and wherein said source and said receiver are positioned adjacent a juncture of said first and second surfaces.

10. A wall construction, comprising:
a wall having means defining a doorway therein;
a door supported adjacent said wall for movement relative to said doorway from one of an open position and a closed position to the other of said open and closed positions without moving in a first direction in which earth gravitational force acts upon said door;
an object sensing arrangement positioned relative to said door for sensing presence of an object adjacent an end surface of said door and providing signaling indicative of said object presence, wherein said end surface of said door faces in a second direction opposite said first direction.

11. The wall construction of claim 10, wherein said object sensing arrangement includes an electromagnetic radiation source for emitting a beam of electromagnetic radiation, and an electromagnetic radiation receiver positioned to receive said electromagnetic radiation beam unless said beam is interrupted by an object.

12. The wall construction of claim 11, wherein said door has a first surface that faces in a third direction perpendicular to said first direction, and wherein said source is positioned to direct said beam substantially parallel to said first surface when said door is in said closed position.

13. The wall construction of claim 12, wherein said source and said receiver are mounted on said wall to be adjacent respective opposite ends of said first surface when said door is in said closed position.

14. The wall construction of claim 12, wherein said source and said receiver are mounted on said first surface adjacent respective opposite ends thereof.

15. A door assembly, comprising:
a door adapted to be supported for movement from one of an open position and a closed position to the other of said open and closed positions without moving in a first direction in which earth gravitational force acts upon said door; and
an object sensing arrangement positioned on said door for sensing presence of an object adjacent an end surface of said door and providing signaling indicative of said object presence, wherein said end surface of said door faces in a second direction opposite said first direction.

16. The door assembly of claim 15, wherein said object sensing arrangement includes an electromagnetic radiation source for emitting a beam of electromagnetic radiation, and an electromagnetic radiation receiver positioned to receive said electromagnetic radiation beam unless said beam is interrupted by an object.

17. The door assembly of claim 16, wherein said door has a first surface that faces in a third direction perpendicular to said first direction, and wherein said source is positioned to direct said beam substantially parallel to said first surface.

18. The door assembly of claim 17, wherein said source and said receiver are mounted on said first surface adjacent respective opposite ends thereof.

19. The door assembly of claim 15, including a sensor positioned on said door for sensing presence of a further force other than earth gravitational force acting on said door in said first direction and applied to said end surface of said door by said object, and for providing signaling indicative of said presence of said further force.

20. A door monitoring system, comprising:
a wall having means defining a doorway therein;
a door supported adjacent said wall for movement relative to said doorway from one of an open position and a closed position to the other of said open and closed positions without moving in a first direction in which earth gravitational force acts upon said door;
a sensor positioned on said door for sensing presence of a force other than earth gravitational force acting on said door in said first direction, and providing first signaling indicative of said presence;
an object sensing arrangement positioned relative to said door for sensing presence of an object positioned to apply said further force to said door and providing second signaling indicative of said object presence;
a detector for detecting said first and second signaling, said detector located physically separately from said door; and
a first electrically conductive signal path coupled between said detector and said sensor for transferring said first signaling from said sensor to said detector, and a second electrically conductive signal path coupled between said detector and said object sensing arrangement for transferring said second signaling from said object sensing arrangement to said detector, wherein said first and second signal paths traverse a portion of said wall.

21. A door monitoring system, comprising:
a wall having means defining a doorway therein;
a door supported adjacent said wall for movement relative to said doorway from one of an open position and a closed position to the other of said open and closed positions without moving in a first direction in which earth gravitational force acts upon said door;
an object sensing arrangement positioned relative to said door for sensing presence of an object adjacent an end surface of said door and providing signaling indicative of said object presence, wherein said end surface of said door faces in a second direction opposite said first direction;
a detector for detecting said signaling, said detector located physically separately from said door; and
an electrically conductive signal path coupled between said detector and said object sensing arrangement for transferring said signaling from said object sensing arrangement to said detector, wherein said signal path traverses a portion of said wall.
